(19) United States
(12) Patent Application Publication
(10) Pub. No.: US 2018/0045885 A1
(43) Pub. Date: Feb. 15, 2018

(54) METHOD OF MANUFACTURING SEMICONDUCTOR DEVICES, CORRESPONDING DEVICE AND CIRCUIT

(71) Applicant: STMICROELECTRONICS S.R.L., Agrate Brianza (IT)

(72) Inventors: Arturo Luigi CANALI, Concorezzo (IT); Luigi VERGA, Bregnano (IT); Luca MAGGI, Garlate (IT)

(21) Appl. No.: 15/457,637

(22) Filed: Mar. 13, 2017

(30) Foreign Application Priority Data
Aug. 10, 2016 (IT) 102016000084419

(51) Int. Cl. G02B 6/12; H01L 23/538; H01L 23/00; H01L 25/00; H01L 25/065

(52) U.S. Cl. CPC G02B 6/12002; H01L 25/50; H01L 25/0657; H01L 24/09; H01L 23/5381; G02B 2006/12147; H01L 2225/06517; H01L 2225/06548; H01L 2224/09177

(57) ABSTRACT

A method of manufacturing semiconductor devices includes: coupling first and the second substrates by coupling a back surface of the second substrate with a front surface of the first substrate, thereby producing a step-like structure, with an uncovered portion of the front surface of the first substrate left uncovered by the second substrate coupling a first integrated circuit with the uncovered portion of the front surface of the first substrate; and coupling a second integrated circuit with the second substrate and the first integrated circuit by arranging the second integrated circuit extending bridge—like between the second substrate and the first integrated circuit.

### BACKGROUND

### Technical Field

The description relates to manufacturing semiconductor devices such as, e.g., integrated circuits.

One or more embodiments may be applied to manufacturing semiconductor devices including both electrical and optical portions.

### Description of the Related Art

Electrical connections may play a significant role in high bit rate applications in semiconductor devices. This may involve both signal and power integrity; poor electrical connections may thus have a negative effect on overall performance.

Certain types of semiconductor devices, such as, e.g., semiconductor devices based on a 3D approach (namely, including a semiconductor die over another semiconductor die, as possibly used in silicon photonics applications) may exhibit certain limitations in terms of electrical connections.

### BRIEF SUMMARY

One or more embodiments may facilitate achieving power and signal integrity without significant process changes in respect of, e.g., electrical integrated circuits (EIC' s) and optical integrated circuits (OIC's).

According to one or more embodiments, a method of manufacturing semiconductor devices includes:

coupling first and the second substrates to each other, the first substrate having a front surface and a back surface, and the second substrate having a front surface and a back surface, the coupling including coupling the back surface of the second substrate with the front surface of the first substrate, thereby producing a step-like structure, with a portion of the front surface of the first substrate left uncovered by the second substrate,

coupling a first integrated circuit with the front surface of the first substrate at said portion left uncovered by the second substrate, and

coupling a second integrated circuit with said second substrate and said first integrated circuit by arranging said second integrated circuit extending bridge—like between said second substrate and said first integrated circuit.

One or more embodiments may relate to a corresponding semiconductor device and a corresponding circuit.

The claims are an integral part of the technical disclosure of one or more embodiments as provided herein.

One or more embodiments may provide a sort of package-based solution, without modifying appreciably the diffusion process.

One or more embodiments may involve using an “organic” package including two different portions attached one over the other, so that a step-wise shape may result.

One or more embodiments may include an electrical integrated circuit (hereinafter briefly, EIC) attached, e.g., via copper pillars partially onto an optical integrated circuit (hereinafter briefly, OIC) and partially on such a step-wise package giving rise to a sort of bridge-like arrangement.

### BRIEF DESCRIPTION OF THE SEVERAL VIEWS OF THE DRAWINGS

One or more embodiments will now be described, by way of example only, with reference to the annexed figures, wherein:

FIGS. 1 and 2 are a sectional view and a plan view, respectively, of one or more embodiments,

FIG. 3, including two portions designated a) and b) schematically represent possible steps in embodiments,

FIG. 4 is a sectional exploded view of one or more embodiments,

FIG. 5 is a sectional view of one or more embodiments,

FIG. 6 is an enlarged view of portions of FIG. 5 as indicated by arrows VI,

FIG. 7 is a sectional exploded view of one or more embodiments, and

FIG. 8 is a schematic view of two devices on a support.

It will be appreciated that, for the sake of clarity and simplicity, the various figures, and portions of such figures, may not be drawn to a same scale.

### DETAILED DESCRIPTION

In the ensuing description, one or more specific details are illustrated, providing an in-depth understanding of examples of embodiments of the instant description. The embodiments may be obtained by one or more of the specific details or with other methods, components, materials, and so on. In other cases, known structures, materials or operations are not illustrated or described in detail so that certain aspects of embodiment will not be obscured.

Reference to “an embodiment” or “one embodiment” in the framework of the present description is intended to indicate a particular configuration, structure, characteristic described in relation to the embodiment is compliance in at least one embodiment. Hence, phrases such as “in an embodiment” or “in one (or more) embodiments” that may be present in one or more points in the present description do not necessarily refer to one and the same embodiment. Moreover, particular conformation, structures or characteristics as exemplified in connection with any of the figures may be combined in any other quite way in one or more embodiments as possibly exemplified in other figures.

The references used herein are provided merely for convenience and hence do not define the extent of protection or the scope of the embodiments.

A current approach for, e.g., silicon photonics applications, is a so-called 3D approach, where an electrical integrated circuit (EIC) is mounted, e.g., by flip-chip mounting, on an optical integrated circuit (OIC).

Electrical connections between the EIC and the OIC may be provided, e.g., by copper pillars deposited partially on the OIC and partially on the EIC. Assembling the EIC on the OIC may involve a wafer—level process, e.g., by reflow of the solder paste of the copper pillars obtained by means of a mass reflow process. The resulting 3D structure may be tested at wafer level (e.g., during Electro—Optical Wafer Sorting—EOWS).

The 3D wafer may then be singulated and each 3D semi-finished device assembled onto, e.g., an organic package for characterization activities. Alternatively, it can be directly mounted on an end—user board, e.g., within a module.

Electrical connections between the 3D assembly and the package (or board) may be provided via wire bonding.

Due to the length and resistance of the electrical path from the copper pillars to the wire bond pads, various issues may arise in terms of power and signal integrity.

A possible way of addressing these issues may involve providing so-called through silicon vias (TSVs) in the OIC, so that the electrical connections are moved from the top side of the OIC to its bottom side and then routed to the proper side, e.g., via a re-distribution layer (RDL).

Connection to the package/board may be provided, e.g., via solder bumps.

Such an approach may lead to changes in the front end and the back end processes of the OIC. Moreover, changes may be made also in the assembly flow.

Documents such as:
M. Deo: “Enabling Next-Generation Platforms Using Altera' s 3D System-in-Package Technology,” June 2015, Altera Corporation, available on the internet at altera.com/content/dam/altera-www/global/en_US/pdfs/literature/wp/wp-01251-enabling-nextgen-with-3d-system-in-package.pdf
A. Hayakawa, et al.: “A 25 Gbps Silicon Photonic Transmitter and Receiver With a Bridge Structure for CPU Interconnects,” Proceedings Optical Fiber Communication Conference, 22-26 March 2015, Los Angeles, Calif., U.S., Th1G.2,
   are exemplary of activities in such area.

One or more embodiments address the issues discussed previously by means of a sort of package-based solution, without modifying appreciably the diffusion process.

One or more embodiments may involve using an “organic” package including two different portions attached one over the other, so that a final step-wise shape may result.

Briefly, one or more embodiments may include an electrical integrated circuit (hereinafter, briefly, EIC) attached, e.g., with copper pillars at least partially onto an optical integrated circuit (hereinafter, briefly, OIC) and partially on the resulting step-wise package giving rise to a sort of bridge-like arrangement.

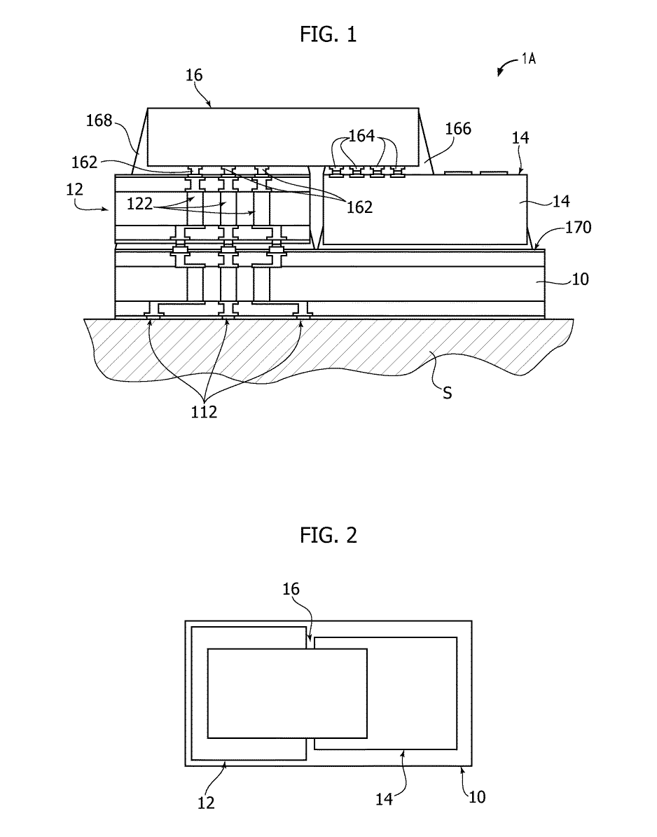

A device 1A according to such an arrangement according to one embodiment of the present disclosure is schematically represented in FIGS. 1 and 2. The device includes a bottom substrate 10 onto which a top substrate 12 and an OIC (e.g., a silicon photonics chip) 14 may be mounted. An EIC 16 may be mounted on top of the substrate 12 and the OIC 14 by extending bridge-like between them.

The resulting 3D arrangement may be located on a support S such as, e.g., an organic package for characterization activities or an end—user board, e.g., within a module.

FIG. 2 is a plan view corresponding to FIG. 1 showing a possible arrangement of the various elements 10, 12, 14 and 16. FIG. 2 highlights the fact that, in one or more embodiments, elements such as, e.g., 12, 14 and 16 may have different dimensions and shapes.

Further details of an arrangement as exemplified in FIG. 1 will be provided in the following by referring, e.g., to FIG. 5.

One or more embodiments may facilitate achieving power integrity by avoiding long traces on the OIC 14, which may represent the less performant chip.

Signals within the structure represented in FIG. 1 may be routed on the EIC 16 and on the substrate 10, 12 thus facilitating achieving power integrity, by taking advantage, e.g., of extensive expertise and experience achieved in that respect in microelectronics.

Achieving enhanced signal integrity may be facilitated in one or more embodiments by providing on the substrates 10, 12 electrically conductive lines (so-called tracks or traces) of an impedance matched type.

In one or more embodiments a structure as exemplified in FIGS. 1 and 2 may be regarded as including a package in turn including a first (“bottom”) substrate 10 and a second (“top”) substrate 12.

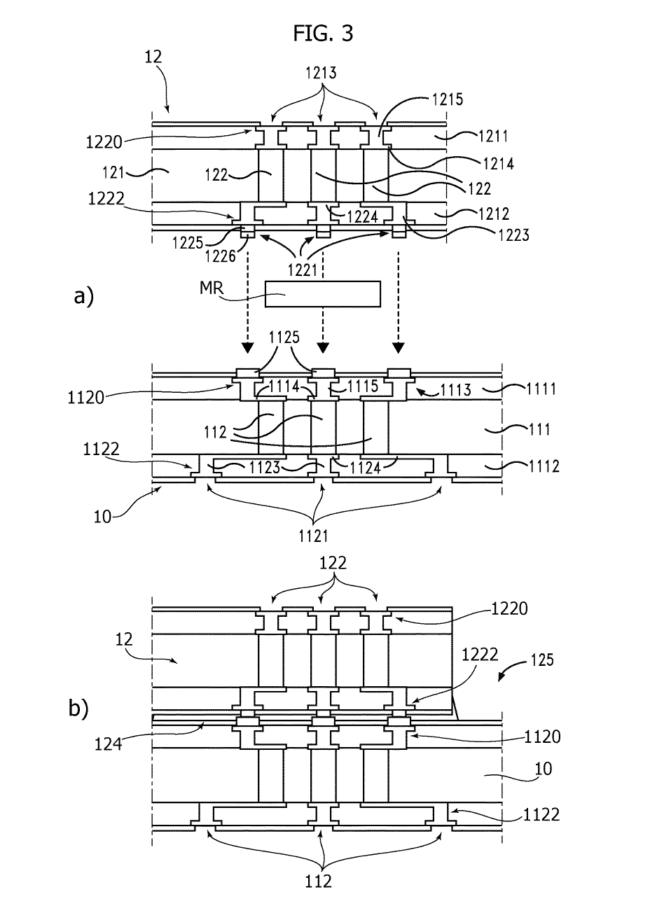

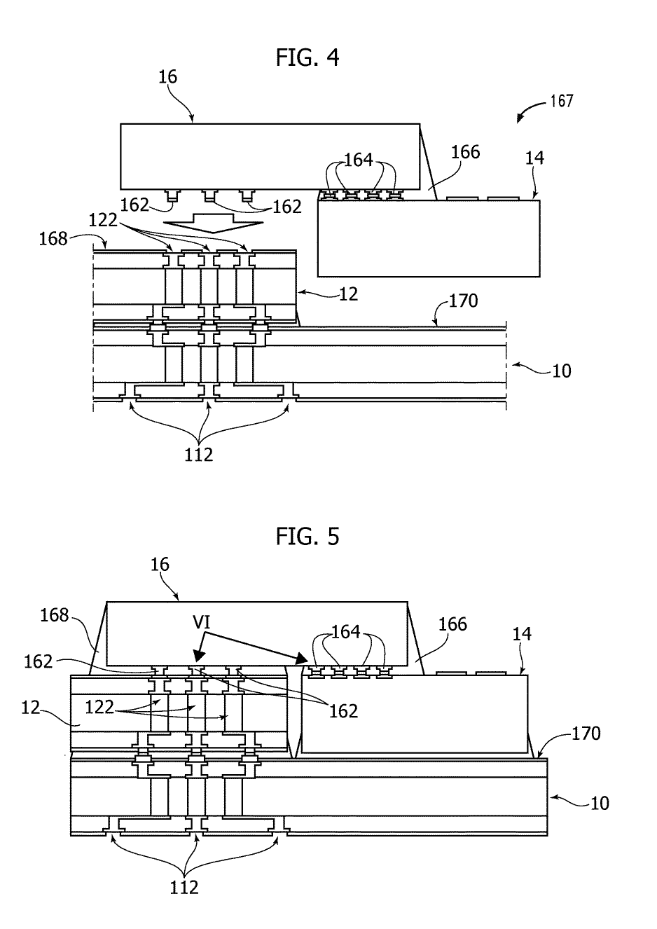

In one or more embodiments, the two substrates 10, 12 may be assembled (e.g., soldered at 1125, 1226) by giving rise to a step-wise structure as visible, e.g., in portion b) of FIG. 3 or in the bottom part of FIG. 4, e.g., by
providing a first substrate 10 having a front (top) surface and a back (bottom) surface,
providing a second substrate 12 having a front (top) surface and a back (bottom) surface,
coupling the first substrate 10 and the second substrate 12 by coupling the back or bottom surface of the second substrate 12 with the front or top surface of the first substrate 10, thereby producing a step-like structure 125, with a portion of the front or top surface of the first substrate 10 left uncovered by the second substrate 12.

In one or more embodiments, having two distinct substrates (e.g., 10, 12) makes it possible, e.g., to use different materials for these two portions.

One or more embodiments thus make it possible to select materials suited for possibly different specifications in terms of electrical and thermal performance.

Organic and ceramic materials or glass substrates may represent an option for the bottom substrate 10. This may also apply to the top substrate 12 with semiconductors such as silicon being another viable option (e.g., for the top substrate 12).

In one or more embodiments, the top substrate 12 may facilitate achieving good electrical connections. For that purpose a high-performance organic substrate or ceramic substrate may be adopted.

In one or more embodiments passive components (such as capacitors, resistors and inductances) may be integrated in the top substrate 12. By resorting to such an approach, such components may be provided (very) close to the EIC 16 thus facilitating improving the overall electrical performance of the EIC 16.

In the embodiment shown in FIG. 3, the top substrate 12 includes a core substrate 121 sandwiched between top and bottom dielectric layers 1211, 1212. As indicated, a semiconductor material such as, e.g., silicon may be a viable candidate for the core substrate 121 of the top substrate 12. Alternatively, other known materials could be used for the core substrate 121, such as ceramics and organic materials.

Electrically conductive vias 122, such as through-silicon vias (TSV) in the case of a silicon substrate, may be adopted for electrical connections through the core substrate 121 of the top substrates 12, without making the diffusion more complicated, this being otherwise a standard process for silicon interposers (with no active or photonic devices integrated in an interposer).

The same basic principles may also apply to the bottom substrate 10 which includes a core substrate 111 which, as indicated, may include an organic, semiconductor, or ceramic substrate. As with the top substrate 12, the core substrate 111 is sandwiched between top and bottom dielectric layers 1111, 1112.

Electrically conductive vias as schematically indicated at 112, may be again resorted to in one or more embodiments, which extend through the core substrate 111, of the bottom substrate 10.

Extending through the top dielectric layer 1211 of the top substrate 12 are conductive pillars 1213 that are respectively connected to the tops of the electrically conductive vias 122. Each pillar 1213 includes a bottom conductive pad 1214, a conductive via 1215, and a top conductive pad 1220.

Extending through the bottom dielectric layer 1212 of the top substrate 12 are conductive pillars 1221 that are respectively connected to bottoms of the electrically conductive vias 122. Each pillar 1221 includes a bottom conductive pad 1222, a conductive via 1223, and a top conductive pad 1224. As shown in FIG. 3, some of the vias 1223 may be offset laterally with respect to the top conductive pads 1224 (see left and right vias) such that the pillars form a redistribution layer (RDL) that spaces the bottom conductive pads 1222 with a greater pitch than the top conductive pads 1220 at the top side of the top substrate 12.Thus, in one or more embodiments, the possible presence of two substrates 10, 12 makes it possible to include a sort of “matching network” at the interface therebetween, i.e. the RDL.

In one or more embodiments, the spacing or pitch of the (electrical contact) pads 1220 on the top side of the top substrate 12 may be in the range of, e.g., 150 micron (1 micron=10⁻⁶ m) which facilitates coupling with copper pillars 162 at the lower side of the EIC 16.

In one or more embodiments re-distribution routing of the signals may occur in the top substrate 12, so that the pitch of the pads 1222 on the bottom side of the top substrate 12 may be, e.g., in the range of 250-500 micron (1 micron=10⁻⁶ m), that is larger than pad pitch at the top side of the top substrate 12.

This may be appreciated, e.g., in both portions a) and b) of FIG. 3 by noting, e.g., that the pads 1220 located above the vias 122 may have a closer spacing than the pads 1222) located below the vias 122.

The wider spacing (pitch) at the bottom side may be suitable for copper posts or micro bumps and “solder-on-pad” technology for the attachment with the bottom substrate 10.

In particular, contacting the bottom sides of the bottom conductive pads 1222 are conductive posts 1225, such as copper posts, with solder 1226 contacting the bottom sides of the conductive posts 1225.

In one or more embodiments coupling of the top and bottom substrates 12, 10 may be via soldering technique, e.g., such as mass reflow technology MR.

Like the top substrate 12, extending through the top dielectric layer 1111 of the bottom substrate 10 are conductive pillars 1113 that are respectively connected to the tops of the electrically conductive vias 112. Each pillar 1113 includes a bottom conductive pad 1114, a conductive via 1115, and a top conductive pad 1120. Some of the vias 1113 may be offset laterally with respect to the top conductive pads 1120 (see left and right vias) such that the pillars form a redistribution layer (RDL) that spaces the top conductive pads 1120 with a greater pitch than the vias 112.

Extending through the bottom dielectric layer 11112 of the bottom substrate 10 are conductive pillars 1121 that are respectively connected to bottoms of the electrically conductive vias 112. Each pillar 1121 includes a bottom conductive pad 1122, a conductive via 1123, and a top conductive pad 1124. Some of the vias 1123 may be offset laterally with respect to the top conductive pads 1124 (see left and right vias) such that the pillars form a redistribution layer (RDL) that spaces the bottom conductive pads 1122 with a greater pitch than the vias 112.

On the top sides of the top conductive pads 1120 may be placed additional solder 1125 that combines with the solder 1226 during the mass reflow soldering to provide a secure electrically connection between the bottom and top substrates 10, 26.

An underfill 124 (see FIG. 3) may be dispensed in one or more embodiments between the top and bottom substrates 12 and 10 for mechanical reliability.

In one or more embodiments, pad spacing (pitch) of the pads 1120 at the top surface of the bottom substrate 10 may correspond to the pad spacing of the pads 1222 at the bottom surface of the top substrate 12.

In one or more embodiments, re-distribution routing may take place within the bottom substrate 10 giving rise to pad pitch (spacing) of the pads 1122 at the bottom side of the bottom substrate 10 of, e.g., 500 micron (1 micron=10⁻⁶ m) or larger, which may be larger than the pad spacing of the pads 1120 at the top surface of the bottom substrate 10.

The bottom layer of the bottom substrate 10 may include, e.g., a standard Land Grid Array (LGA) adapted to be, e.g., soldered to the underlying board S.

In one or more embodiments pad finishing may be selected to be compatible with a certain assembly flow.

For instance, Ni-Au finishing may be considered for all of the conductive pads of the device, including top and bottom pads of the top and bottom substrates, as this preserves Controlled Collapse Chip Connection (C4) pad wettability after the package preparation phase.

By way of example (these indications are merely exemplary and do not limit the scope of the embodiments) the core substrates 111, 121 of both the bottom substrate 10 and the top substrate 12 may include a material such as glass epoxy multilayer material, halogen free, high Tg, high elastic module and low CTE (Coefficient of Thermal Expansion), with, e.g., organic substrates of the E705G or E700G families representing viable choices.

Also by way of example (again these indications are merely exemplary and do not limit the scope of the embodiments) the core substrates 111, 121 of both the bottom substrate 10 and the top substrate 12 may include a material with a thickness of, e.g., 400 micron (1 micron=10⁻⁶ m).

In one or more embodiments, the dielectric layers 1111, 1112, 1211, 1212 on both sides of such core substrates may be a layer of build up material, halogen free, low CTE and low loss tangent, with the ABF GX and ABF GZ families being a viable choice for organic substrates.

FIGS. 4 and 5 are exemplary of the possibility of providing at the lower side of the EIC 16 two sets of pillars 162, 164 for coupling with the top substrate 12 (pillars 162) and with the OIC 14 (pillars 164).

In one or more embodiments, the pillars 162, 164 in the two sets may exhibit substantially identical characteristics (being, e.g., copper pillars).

In one or more embodiments, the pillars 162, 164 in the two sets may be arranged with a different spacing/pitch, e.g., with the pillars 162 (for coupling the EIC 16 with the top substrate 12) having a pitch/spacing in the range of, e.g., 150 micron (1 micron=10⁻⁶ m), that is larger than the pitch/spacing of the pillars 164 (for coupling the EIC 16 with the OIC 14) these latter pillars having pitch/spacing of, e.g., 50 micron (1 micron=10⁻⁶ m).

In one or more embodiments the OIC 14 may be back grinded in order to reduce the thickness thereof to be at least slightly smaller than the thickness of the top substrate 12; this may facilitate mechanical assembly by also taking into account possible tolerances.

Coupling by copper pillars 162, 164 may facilitate a coupling, e.g., by thermo-compression techniques.

In one or more embodiments, an underfill (e.g., a non-conductive paste—NCP) may be dispensed as indicated at 166, e.g., between the OIC 14 and EIC 16 to facilitate achieving mechanical reliability.

In one or more embodiments (see, e.g., FIG. 4), the OIC 14 and the EIC 16 may be first coupled to each other (e.g., via the pillars 164) to produce a sort of a “cantilever” structure 167 which may then be soldered on the step-wise package formed by the top substrate 12 mounted on the bottom substrate 10.

Again, thermo-compression may be an option for achieving such connection with mass reflow being one of the possible alternatives.

An underfill (e.g., a non-conductive paste or NCP as schematically indicated at 168) may be dispensed between the two parts connected in order to facilitate achieving mechanical reliability.

In one or more embodiments, the steps as exemplified in the foregoing may lead to the OIC 14 being somewhat “floating” since (only) the EIC 16 is actually coupled to the substrate (top substrate 12).

In one or more embodiments an adhesive layer (as indicated at 170) may be dispensed between the OIC 14 and the bottom substrate 10. In one or more embodiments this attachment may facilitate achieving mechanical reliability, stress relief and thermal contact for heat sinking.

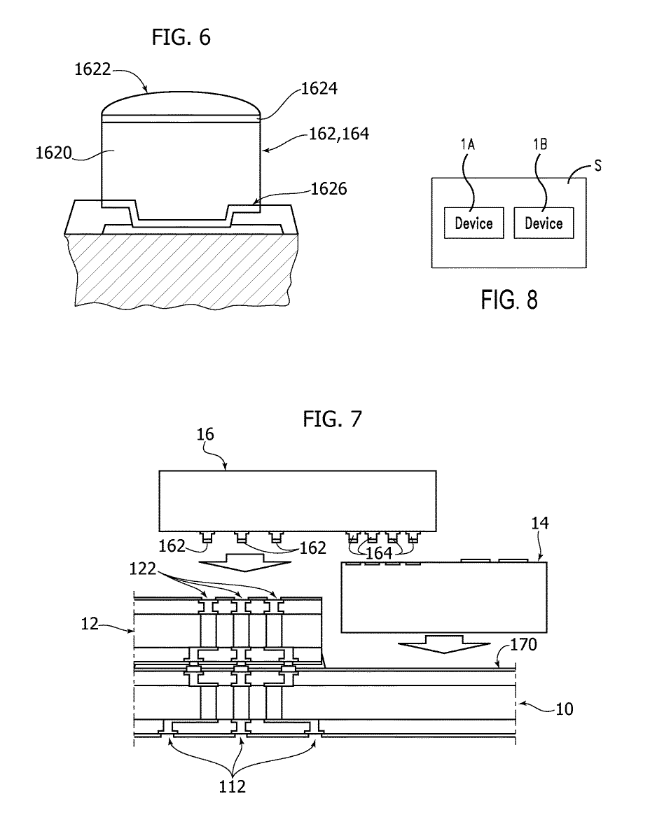

As exemplified in FIG. 6, in one or more embodiments, the pillars 162, 164 may include metal (e.g., copper) body 1620 having an upper soldering pad (e.g., SnAg) 1622 with an, e.g., nickel interface 1624 therebetween and an under bump metallurgy—UBM at 1626. The UBM 1626 may contact an upper conductive pad, such as one of the top conductive pads 1220 on the top substrate 12 for the pillars 162 or similar pads on the top side of the OIC 14

One or more embodiments may permit to overcome assembly limitations related to mechanical tolerances.

In one or more embodiments, each portion of the structure may be assembled to only one another part at a time.

In one or more embodiments interfaces for coupling (e.g., soldering) may be defined by lithography. In one or more embodiments, absorbing the differences in thickness between the OIC 14 and the top substrate 12 may be facilitated by back grinding the OIC 14 to desired thickness.

As discussed previously, in one or more embodiments, achieving mechanical reliability may be facilitated by underfills and/or glues (adhesives)—see, e.g., 124, 168, 170—capable of filling possible avoid regions.

In one or more embodiments, the assembly flow may be varied as schematically represented in FIG. 7, that is with the bottom and top substrates 10, 12 assembled as described previously with the OIC 14 attached to the bottom substrate 10 (e.g., via the adhesive layer 170) and the EIC 16 arranged bridge-like (e.g., soldered in one shot) to the OIC 14 and the top substrate 12.

While permitting attaching the OIC 14 directly on the bottom substrate 16, such an approach, may render compensating the difference in thickness between the OIC 14 and the top substrate 12 more critical. In such embodiments, placement of the OIC 14 may involve a certain degree of accuracy in order to facilitate connection of the EIC 16 simultaneously to the OIC 14 and the top substrate 12.

One or more embodiments may be compatible with subsequent operations of optical coupling, such as “pigtailing” and/or edge coupling and laser module attachment.

One or more embodiments may thus provide a method of manufacturing semiconductor devices, the method including:
providing a first substrate (e.g., 10) for the device, the first substrate having a front surface and a back surface,
providing a second substrate (e.g., 12) for the device, the second substrate having a front surface and a back surface,
coupling (e.g., at1125, 1226, 124) the first and the second substrates by coupling the back surface of the second substrate with the front surface of the first substrate, thereby producing a step-like structure, with a portion of the front surface of the first substrate left uncovered by the second substrate,
coupling a first integrated circuit (e.g., 14) with the front surface of the first substrate at said portion left uncovered by the second substrate, and
coupling a second integrated circuit (e.g., 16) with said second substrate and said first integrated circuit by arranging said second integrated circuit extending bridge—like between said second substrate and said first integrated circuit .

In one or more embodiments, said first integrated circuit may include an optical integrated circuit (OIC).

One or more embodiments may include:
coupling said first integrated circuit and said second integrated circuit to produce an assembly including said second integrated circuit extending cantilever-like from said first integrated circuit (see, e.g., FIG. 4, top), and
coupling said assembly including said second integrated circuit extending cantilever—like from said first integrated circuit with said step-like structure.

One or more embodiments may include back grinding said first integrated circuit to adjust the thickness thereof to the height of said step—like structure.

One or more embodiments may include adhesively coupling (e.g., at 170) said first integrated circuit to said first substrate, optionally in the absence of electrical connections therebetween.

One or more embodiments may include electrically coupling said second integrated circuit with said second substrate and said first integrated circuit, said coupling optionally by conductive pillars (e.g., 162, 164).

One or more embodiments may include said electrical coupling by conductive pillars by arranging said pillars in a first set (e.g., 162) and a second set (e.g., 164) for electrically coupling said second integrated circuit with said second substrate and said first integrated circuit, respectively, the pillars in said first set optionally having a wider spacing than the pillars in said second set.

One or more embodiments may include coupling said first substrate and said second substrate by soldering, optionally with mass reflow (e.g., MR) soldering and/or with an underfill (e.g., 124) therebetween.

One or more embodiments may include providing at least one of said first substrate and said second substrate with electrical contact pads at their front surfaces and at their back surfaces, wherein:
the electrical contact pads at the back surfaces (e.g., 1122, 1222) may have a different, optionally wider spacing than the electrical contact pads at the front surfaces (e.g., 1120, 1220), and/or
at least one of the first substrate and the second substrate may have electrically conductive vias (e.g., 112, 122) extending therethrough.

In one or more embodiments a semiconductor device may include:
a first substrate having a front surface and a back surface,
a second substrate having a front surface and a back surface, wherein the first substrate and the second substrate are coupled in a step-like structure with the back surface of the second substrate coupled with a front surface of the first substrate and a portion of the front surface of the first substrate left uncovered by the second substrate ,
a first integrated circuit coupled with the front surface of the first substrate at said portion left uncovered by the second substrate, and
a second integrated circuit coupled with said second substrate and said first integrated circuit with said second integrated circuit arranged extending bridge—like between said second substrate and said first integrated circuit, said first integrated circuit optionally including an optical integrated circuit.

One or more embodiments may include a semiconductor device as obtained with the method discussed previously.

One or more embodiments may include a plurality of semiconductor devices 1A, 1B according to one or more embodiments arranged on a support substrate S as shown in FIG. 8).

Without prejudice to the underlying principles, the details and embodiments may vary, even significantly, with respect to what has been described previously, without departing from the extent of protection.

The various embodiments described above can be combined to provide further embodiments. These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. A method of manufacturing semiconductor devices, the method comprising:
coupling first and the second substrates to each other, the first substrate having a front surface and a back surface, and the second substrate having a front surface and a back surface, the coupling including coupling the back surface of the second substrate with the front surface of the first substrate, thereby producing a step-like structure, with a portion of the front surface of the first substrate left uncovered by the second substrate,
coupling a first integrated circuit with the front surface of the first substrate at said portion left uncovered by the second substrate, and
coupling a second integrated circuit with said second substrate and said first integrated circuit by arranging said second integrated circuit extending bridge—like between said second substrate and said first integrated circuit.

2. The method of claim 1, wherein said first integrated circuit includes an optical integrated circuit.

3. The method of claim 1, including:
coupling said first integrated circuit and said second integrated circuit to produce an assembly including said second integrated circuit extending cantilever-like from said first integrated circuit, and
coupling said assembly including said second integrated circuit extending cantilever—like from said first integrated circuit with said step-like structure.

4. The method of claim 1, including back grinding said first integrated circuit to adjust a thickness thereof to a height of said step—like structure.

5. The method of claim 1, including adhesively coupling said first integrated circuit to said first substrate.

6. The method of claim 1, including electrically coupling said second integrated circuit with said second substrate and said first integrated circuit.

7. The method of claim 6, wherein said electrically coupling includes electrically coupling said second integrated circuit with said second substrate using a first set of conductive pillars and electrically coupling said second integrated circuit with said first integrated circuit using a second set of conductive pillars.

8. The method of claim 1, including coupling said first substrate and said second substrate by soldering.

9. The method of claim 1, including:
providing first electrical contact pads at the front surface of one of said first substrate and said second substrate and providing second electrical contact pads at the back surface of the one of said first substrate and said second substrate, wherein the first electrical contact pads have a different spacing than the second electrical contact, and
forming electrically conductive vias extending through the one of the first substrate and the second substrate.

10. A semiconductor device, including:
a first substrate having a front surface and a back surface,
a second substrate having a front surface and a back surface, wherein the first substrate and the second substrate are coupled in a step-like structure in which the back surface of the second substrate is coupled with a front surface of the first substrate and a portion of the front surface of the first substrate left uncovered by the second substrate,
a first integrated circuit coupled with the front surface of the first substrate at said portion left uncovered by the second substrate, and
a second integrated circuit coupled with said second substrate and said first integrated circuit with said second integrated circuit arranged extending bridge-like between said second substrate and said first integrated circuit.

11. The semiconductor device of claim 10, wherein said first integrated circuit includes an optical integrated circuit.

12. The semiconductor device of claim 10, further comprising an adhesive layer adhesively coupling said first integrated circuit to said first substrate.

13. The semiconductor device of claim 10, wherein said second integrated circuit is electrically coupled with said second substrate and said first integrated circuit.

14. The semiconductor device of claim 10, further comprising:
a first set of conductive pillars electrically coupling said second integrated circuit with said second substrate; and
a second set of conductive pillars electrically coupling said second integrated circuit with said first integrated circuit.

15. The semiconductor device of claim 10, including:
first electrical contact pads at the front surface of said second substrate and electrically coupled to the second integrated circuit;
second electrical contact pads at the back surface said second substrate and electrically coupled to the first substrate; and
electrically conductive vias extending through the second substrate, the electrically conductive via respectively coupling the first electrical contact pads to the second electrical contact pads.

16. The semiconductor device of claim 15, wherein the first electrical contact pads have a different spacing than the second electrical contact pads.

17. An electrical circuit, comprising:
a support member; and
a plurality of semiconductor devices arranged on the support member, each semiconductor device including:
a first substrate having a front surface and a back surface,
a second substrate having a front surface and a back surface, wherein the first substrate and the second substrate are coupled in a step-like structure in which the back surface of the second substrate is coupled with a front surface of the first substrate and a portion of the front surface of the first substrate left uncovered by the second substrate,
a first integrated circuit coupled with the front surface of the first substrate at said portion left uncovered by the second substrate, and
a second integrated circuit coupled with said second substrate and said first integrated circuit with said second integrated circuit arranged extending bridge-like between said second substrate and said first integrated circuit.

18. The electrical circuit of claim 17, wherein each of the semiconductor devices further includes:
a first set of conductive pillars electrically coupling said second integrated circuit with said second substrate; and
a second set of conductive pillars electrically coupling said second integrated circuit with said first integrated circuit.

19. The electrical circuit of claim 17, wherein each of the semiconductor devices further includes:
first electrical contact pads at the front surface of said second substrate and electrically coupled to the second integrated circuit;
second electrical contact pads at the back surface said second substrate and electrically coupled to the first substrate; and
electrically conductive vias extending through the second substrate, the electrically conductive via respectively coupling the first electrical contact pads to the second electrical contact pads.

20. The electrical circuit of claim 17, wherein, in each of the semiconductor devices, the first electrical contact pads have a different spacing than the second electrical contact pads.
